(19) United States
(12) Patent Application Publication
(10) Pub. No.: US 2024/0288775 A1
(43) Pub. Date: Aug. 29, 2024

(54) SUBSTRATE PROCESSING METHOD, SUBSTRATE PROCESSING APPARATUS AND SUBSTRATE PROCESSING SYSTEM

(71) Applicant: Tokyo Electron Limited, Minato-ku, Tokyo (JP)

(72) Inventor: Soichiro OKADA, Koshi City, Kumamoto (JP)

(21) Appl. No.: 18/573,627

(22) PCT Filed: Jun. 16, 2022
(86) PCT No.: PCT/JP2022/024182

§ 371 Date: Dec. 22, 2023

(30) Foreign Application Priority Data
Jun. 24, 2021 (JP) 2021-104878

(51) Int. Cl. G03F 7/20; H01L 21/311; H01L 21/67

(52) U.S. Cl. CPC G03F 7/2004; H01L 21/31111; H01L 21/31133; H01L 21/31144; H01L 21/67075

(57) ABSTRACT

A substrate processing method includes: insolubilizing a resist pattern with respect to a phosphoric acid solution by irradiating a substrate, on which an organic film, a silicon-containing inorganic film, and the resist pattern are sequentially stacked in this order from below, with ultraviolet rays; after the insolubilizing the resist pattern, removing the silicon-containing inorganic film exposed from the resist pattern by supplying the phosphoric acid solution to the substrate; and after the removing the silicon-containing inorganic film, transferring the resist pattern to the organic film by performing an etching process on the substrate.

### TECHNICAL FIELD

The present disclosure relates to a substrate processing method and a substrate processing system.

### BACKGROUND

Patent Document 1 discloses a technique in which an organic underlayer film to which a thermal acid generator (TAG) is added, an inorganic intermediate film, and a photoresist film are formed on a target substrate, and the target substrate is etched and processed.

### PRIOR ART DOCUMENTS

### Patent Documents

Patent Document 1: Japanese Laid-Open Publication No. 2009-109768

### SUMMARY

A technique according to the present disclosure makes it possible to appropriately transfer a resist pattern to an organic film when the organic film, a silicon-containing inorganic film, and the resist pattern are sequentially stacked in this order from below.

According to one embodiment of the present disclosure, a substrate processing method includes insolubilizing a resist pattern with respect to a phosphoric acid solution by irradiating a substrate, on which an organic film, a silicon-containing inorganic film, and the resist pattern are sequentially stacked in this order from below, with ultraviolet rays, removing the silicon-containing inorganic film exposed from the resist pattern by supplying the phosphoric acid solution to the substrate after the insolubilizing the resist pattern, and transferring the resist pattern to the organic film by performing an etching process on the substrate after the removing the silicon-containing inorganic film.

According to the present disclosure, when an organic film, a silicon-containing inorganic film, and a resist pattern are sequentially stacked from below, the resist pattern is capable of being appropriately transferred to the organic film.

### BRIEF DESCRIPTION OF DRAWINGS

FIG. 1 is an explanatory diagram schematically illustrating a configuration of a wafer processing system as a substrate processing system, having a coating and developing processing apparatus as a substrate processing apparatus, according to the present embodiment.

FIG. 2 is an explanatory diagram schematically illustrating an internal configuration of the coating and developing processing apparatus.

FIG. 3 is a diagram schematically illustrating a front side and the internal configuration of the coating and developing processing apparatus.

FIG. 4 is a diagram schematically illustrating a rear side and the internal configuration of the rear side of the coating and developing processing apparatus.

FIG. 5 is a longitudinal cross-sectional view schematically illustrating a configuration of a wet etching unit.

FIG. 6 is a transverse cross-sectional view schematically illustrating the configuration of the wet etching unit.

FIG. 7 is a longitudinal cross-sectional view schematically illustrating a configuration of an irradiation unit.

FIG. 8 is a flowchart illustrating main processes of an example of wafer processing.

FIGS. 9A to 9H are schematic partial cross-sectional views illustrating a state of a wafer in each process of wafer processing.

FIG. 10 is a diagram illustrating an SEM image of a wafer after being irradiated with ultraviolet rays at an exposure amount of 2,000 mJ/cm² in a state in which the wafer is formed by sequentially stacking a SoC film, a SiC film, and a resist pattern (having a thickness of approximately 50 nm and a line width of approximately 20 nm) from below on a Si bare wafer.

FIG. 11 is a diagram illustrating an SEM image of a wafer, which has been irradiated with ultraviolet rays, after being immersed in a phosphoric acid solution with a concentration of 85 wt % and a temperature of 150 degrees C. for 90 seconds.

FIG. 12 is a diagram illustrating an SEM image of a wafer, which has been wet-etched, after being subjected to an ashing process in a state in which the wafer is wet-etched.

FIG. 13 is a longitudinal cross-sectional view schematically illustrating another example of the wet etching unit.

### DETAILED DESCRIPTION

In a manufacturing process of semiconductor devices, etc., a resist coating process of applying a resist solution to a substrate such as a semiconductor wafer (hereinafter referred to as a “wafer”) to form a resist film, an exposure process of exposing the resist film, and a developing process of developing the exposed resist film are sequentially performed to form a resist pattern on the substrate. After the resist pattern is formed, a target layer is etched using the resist pattern as a mask, so that a predetermined pattern is formed in the target layer. In the related art, dry etching is used for etching.

However, with the miniaturization of a semiconductor device, there is a demand for miniaturization of a resist pattern, and there is also a demand for thinning of the resist pattern so as not to generate pattern collapse even in the miniaturized resist pattern.

Additionally, when the resist pattern is thin and an etching selectivity of a target layer with respect to the resist pattern is low during dry etching, an organic film, a silicon-containing inorganic film, and the resist pattern may be sequentially stacked on the target layer. When the dry etching is performed on the stacked substrate in this way, the pattern of the resist pattern is transferred in the order of the silicon-containing inorganic film, the organic film, and an etching target film.

In recent years, miniaturization of semiconductor devices and miniaturization of resist patterns have further advanced, and the demand for thinning of the resist pattern has also advanced further. For example, in some cases, the film thickness of the resist pattern may be required to be 50 nm or less.

However, when dry etching is performed on the silicon-containing inorganic film using such a thin resist pattern as a mask, the resist pattern may disappear during the etching, and the pattern of the resist pattern may not be transferred to the silicon-containing inorganic film. In this case, the transfer to the organic film and the transfer to the etching target film will also be defective.

Therefore, in the case in which an organic film, a silicon-containing inorganic film, and a resist pattern are sequentially stacked from below, a technique according to the present disclosure makes it possible to appropriately transfer the resist pattern to the organic film and a target layer below the organic layer.

Hereinafter, a substrate processing method and a substrate processing apparatus according to the present embodiment will be described with reference to the drawings. In this specification and the drawings, elements having substantially the same functional configurations are designated by the same reference numerals to omit redundant explanation.

### <Wafer Processing System>

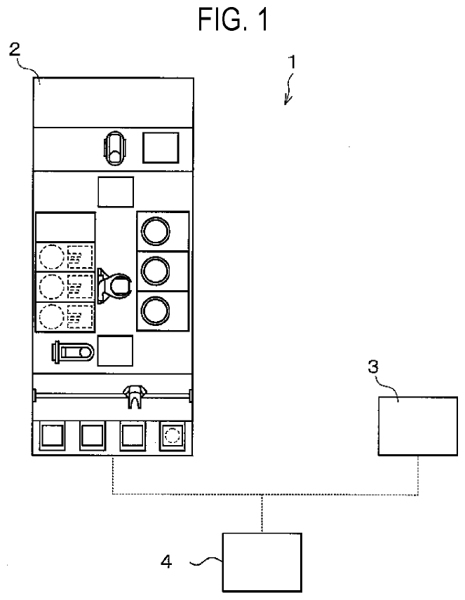

FIG. 1 is an explanatory diagram schematically illustrating a configuration of a wafer processing system as a substrate processing system, having a coating and developing processing apparatus as a substrate processing apparatus, according to the present embodiment.

A wafer processing system 1 of FIG. 1 includes a coating and developing processing apparatus 2, an etching processing apparatus 3, and a controller 4.

The coating and developing processing apparatus 2 serves to perform a photolithography process on a wafer as a substrate. In this coating and developing processing apparatus 2, the formation of a resist film and the like are performed.

The etching processing apparatus 3 serves to perform a dry etching process on the wafer. As the etching processing apparatus 3, for example, a reactive ion etching (RIE) apparatus that performs the dry etching process on the wafer by the plasma processing is used. This etching processing apparatus 3 performs, for example, etching of a silicon inorganic film using a resist pattern and a pattern of a spin-on carbon (SoC) film as a mask, as described later.

The controller 4 controls the operation of each apparatus. The controller 4 is, for example, a computer equipped with a CPU, a memory, or the like and has a program storage (not illustrated). The program storage stores programs for performing wafer processing described below in the wafer processing system 1 by controlling the operations of drive systems such as the above-described various processing apparatuses and transport apparatuses (not illustrated). The programs have been recorded on a computer-readable storage medium H and may be installed in the controller 4 from the storage medium H. The storage medium H may be transitory or non-transitory. A part or all of the programs may be realized by dedicated hardware (a circuit board).

### <Coating and Developing Processing Apparatus>

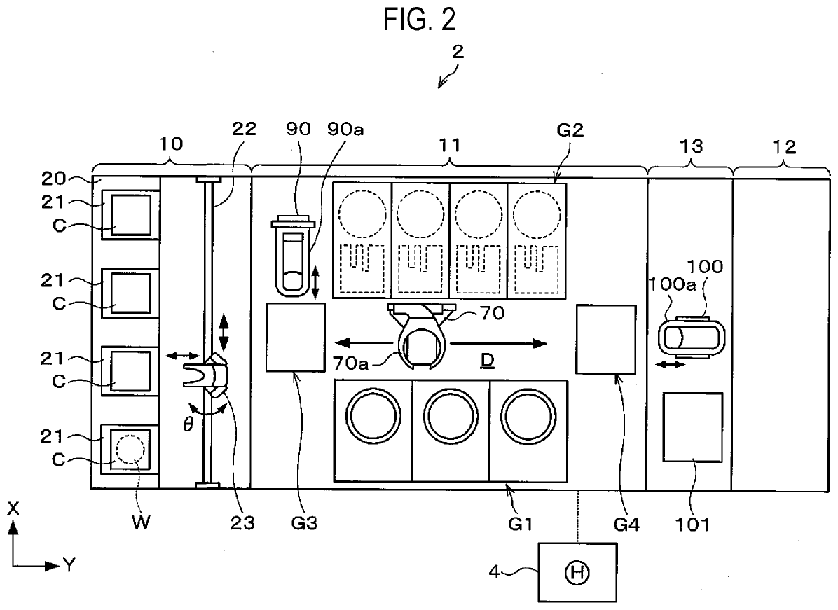

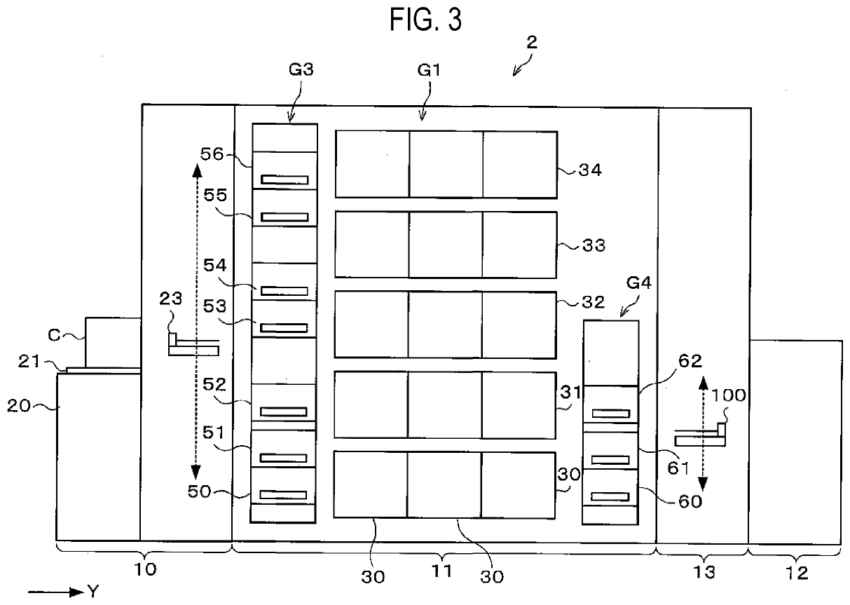

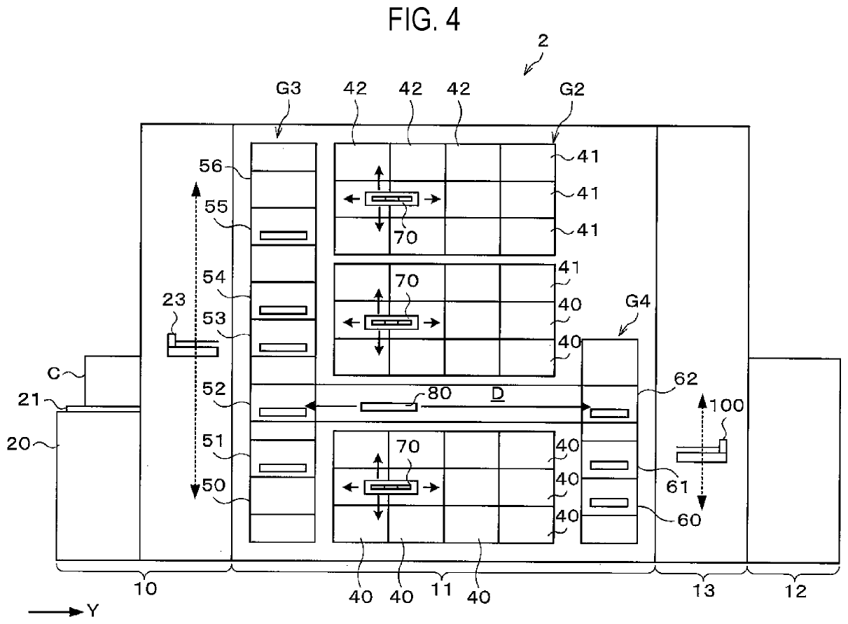

FIG. 2 is an explanatory diagram schematically illustrating an internal configuration of the coating and developing processing apparatus 2. FIGS. 3 and 4 are diagrams schematically illustrating internal configurations of the front side and rear side of the coating and developing processing apparatus 2, respectively.

As illustrated in FIG. 2, the coating and developing processing apparatus 2 includes a cassette station 10 into and from which a cassette C accommodating wafers W is loaded and unloaded, and a processing station 11 having various processing units that perform predetermined processing on the wafers W. The coating and developing processing apparatus 2 has a configuration in which the cassette station 10, the processing station 11, and an interface station 13 that delivers the wafer W between the processing station 11 and an exposure apparatus 12 adjacent to the processing station 11 are integrally connected.

The cassette station 10 is provided with a cassette stage 20. The cassette stage 20 is provided with cassette stage plates 21 on which the cassette C is placed when the cassette C is loaded into or unloaded from the outside of the coating and developing processing apparatus 2.

The cassette station 10 is provided with a wafer transport unit 23 that is movable on a transport path 22 extending in an X direction in the drawing. The wafer transport unit 23 is also movable in an up-down direction and around a vertical axis (in a θ direction) and may transport the wafer W between the cassette C on the cassette stage plate 21 and a delivery unit of a third block G3 of the processing station 11 described later.

In the processing station 11, blocks, for example, four blocks G1, G2, G3, and G4 each including various units, are provided. For example, the first block G1 is provided on the front side (negative side of the X direction in FIG. 2) of the processing station 11, and the second block G2 is provided on the rear side (positive side of the X direction in FIG. 2) of the processing station 11. Further, the third block G3 is provided on the side of the cassette station 10 (negative side of a Y direction in FIG. 2) of the processing station 11, and the fourth block G4 is provided on the side of the interface station 13 (positive side of the Y direction in FIG. 2) of the processing station 11.

In the first block G1, as illustrated in FIG. 3, liquid processing units, for example, a development processing unit 30 as a developer, a SoC film forming unit 31 as an organic film former, a SiC film forming unit 32 as an inorganic film former, a resist coating unit 33, and a wet etching unit 34 as a wet etcher, are sequentially arranged from below.

The development processing unit 30 performs developing processing on the wafer W. Specifically, the development processing unit 30 forms a resist pattern by supplying a developing liquid to the wafer W on which a resist film is formed.

The SoC film forming unit 31 forms a SoC film by directly coating a material (coating liquid) for the SoC film as an organic film onto a processing target layer, i.e., an etching target layer (e.g., a silicon oxide film), formed on the wafer W.

The SiC film forming unit 32 forms a SiC film by directly coating a material for the SiC film as a silicon-containing inorganic film onto the SoC film formed on the wafer W.

The resist coating unit 33 forms a resist film by directly coating a chemically amplified resist onto the SiC film formed on the wafer W. The chemically amplified resist is, for example, an EUV resist having photosensitivity to EUV and may be an ArF resist or a KrF resist having photosensitivity to an ArF excimer laser or a KrF excimer laser used in immersion exposure.

The wet etching unit 34 etches, i.e., removes, the SiC film exposed from the resist pattern by supplying a phosphoric acid solution to the wafer W which has the resist pattern formed thereon by the development processing unit 30 and has been irradiated with ultraviolet rays by an irradiation unit 41 described later.

For example, three development processing units 30, three SoC film forming units 31, three SiC film forming units 32, three resist coating units 33, and three wet etching units 34 are respectively arranged side by side in a horizontal direction. The number and arrangement of the development processing units 30, the SoC film forming units 31, the SiC film forming units 32, the resist coating units 33, and the wet etching units 34 may be arbitrarily selected.

In addition, in the SoC film forming units 31, the SiC film forming units 32, the resist coating units 33, and the wet etching units 34, the supply of the developing liquid, the formation of the SoC film, the formation of the SiC film, the formation of the resist film, or the supply of the phosphoric acid solution is performed by a spin applying method (also referred to as a spin coating method).

As illustrated in FIG. 4, the second block G2 is provided with a heat treatment unit 40, and an irradiation unit 41 as a reformer.

The heat treatment unit 40 performs heat treatment such as heating and cooling the wafer W.

The irradiation unit 41 insolubilizes the resist pattern with respect to the phosphoric acid solution by irradiating the wafer W, on which the SoC film, the SiC film, and the resist pattern are sequentially stacked from below on an etching target layer, with ultraviolet rays. The ultraviolet rays are irradiated in a low-oxygen atmosphere with an oxygen concentration of 0.1% or less, for example.

The heat treatment unit 40 and the irradiation unit 41 are arranged side by side in an up-down direction and a horizontal direction, and the number and arrangement of the heat treatment units 40 and the irradiation units 41 may be arbitrarily selected.

For example, in the third block G3, delivery units 50, 51, 52, 53, 54, 55, and 56 are sequentially provided in order from below. Further, in the fourth block G4, delivery units 60, 61, and 62 are sequentially provided from below.

As illustrated in FIG. 2, a wafer transport region D is formed in a region surrounded by the first block G1 to the fourth block G4. In the wafer transport region D, a wafer transport unit 70 is arranged.

The wafer transport unit 70 has a transport arm 70a that is movable, for example, in the Y direction, the X direction, the θ direction, and the up-down direction. The wafer transport unit 70 may move within the wafer transport region D to transport the wafer W between the units in the first block G1, the second block G2, the third block G3, and the fourth block G4 located therearound. For example, as illustrated in FIG. 4, wafer transport units 70 are arranged above and below and may transport the wafer W, for example, between units of approximately the same height of each of the blocks G1 to G4.

Further, in the wafer transport region D, a shuttle transport unit 80 that linearly transports the wafer W between the third block G3 and the fourth block G4 is provided.

The shuttle transport unit 80 is movable linearly, for example, in the Y direction in FIG. 4. The shuttle transport unit 80 may transport the wafer W between the delivery unit 52 of the third block G3 and the delivery unit 62 of the fourth block G4 by moving in the Y direction while supporting the wafer W.

As illustrated in FIG. 2, a wafer transport unit 90 is provided adjacent to the positive side of the X direction of the third block G3. The wafer transport unit 90 has a transport arm 90a that is movable, for example, in the X direction, the 0 direction, and the up-down direction. The wafer transport unit 90 may transport the wafer W to each delivery unit in the third block G3 by moving up and down while supporting the wafer W.

The interface station 13 is provided with a wafer transport unit 100 and a delivery unit 101. The wafer transport unit 100 has a transport arm 100a that is movable, for example, in the Y direction, the 0 direction, and the up-down direction. The wafer transport unit 100 may transport the wafer W between each delivery unit in the fourth block G4, the delivery unit 101, and the exposure apparatus 12 while supporting the wafer W on the transport arm 100a, for example.

In the coating and developing processing apparatus 2, the above-described processing units and transport units are controlled by, for example, the controller 4.

### <Wet Etching Unit>

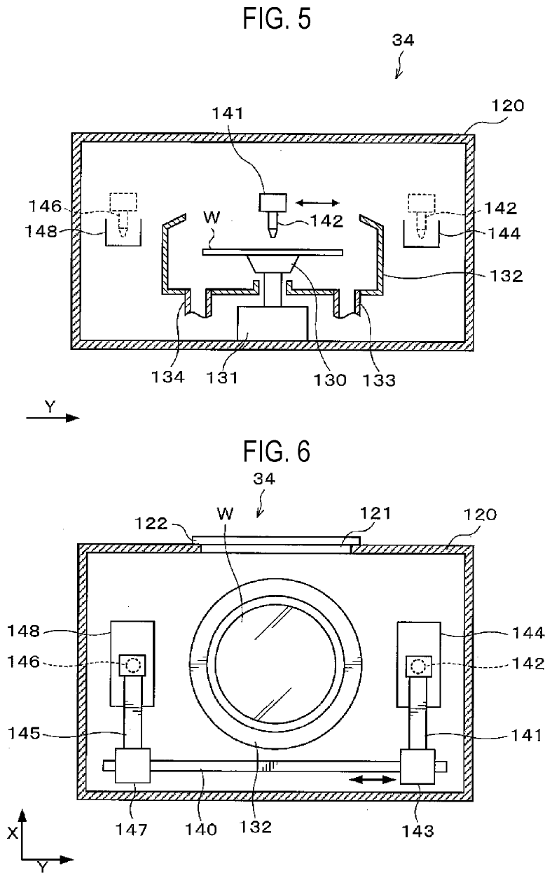

Next, a configuration of the above-mentioned wet etching unit 34 will be described. FIG. 5 and FIG. 6 are a longitudinal cross-sectional view and a transverse cross-sectional view, respectively, schematically illustrating the configuration of the wet etching unit 34.

The wet etching unit 34 has a processing container 120, the interior of which is capable of being closed, as illustrated in FIG. 5. As illustrated in FIG. 6, a loading/unloading port 121 of the wafer W is formed on a surface facing the wafer transport region D of the processing container 120, and the loading/unloading port 121 is provided with an opening/closing shutter 122.

A spin chuck 130 that holds and rotates the wafer W is provided in the center of the processing container 120, as illustrated in FIG. 5. The spin chuck 130 has a horizontal upper surface, and the upper surface is provided with, for example, a suction port (not illustrated) for suctioning the wafer W. The wafer W may be suctioned and held on the spin chuck 130 by suction from the suction port.

The spin chuck 130 is connected to a chuck drive mechanism 131 and may be rotated at a desired speed by the chuck drive mechanism 131. The chuck drive mechanism 131 has a rotation drive source (not illustrated) such as a motor that generates a drive force for rotating the spin chuck 130. In addition, the chuck drive mechanism 131 is provided with an elevating drive source such as a cylinder, and the spin chuck 130 is movable up and down.

A cup 132 that receives and collects liquid scattered or dropped from the wafer W is provided around the spin chuck 130. A discharge pipe 133 for discharging the collected liquid and an exhaust pipe 134 for exhausting an atmosphere inside the cup 132 are connected to the lower surface of the cup 132.

As illustrated in FIG. 6, a rail 140 extending in the Y direction (left-right direction in FIG. 6) is formed on the negative side of the X direction of the cup 132 (downward direction in FIG. 6). The rail 140 is formed, for example, from the outer side of the negative side of the Y direction of the cup 132 (left direction in FIG. 6) to the outer side of the positive side of the Y direction of the cup 132 (right direction in FIG. 6). Arms 141 and 145 are installed on the rail 140.

A dispensing nozzle 142 is supported on the arm 141 as illustrated in FIGS. 5 and 6. The dispensing nozzle 142 dispenses a phosphoric acid liquid. The arm 141 is movable on the rail 140 by a nozzle driver 143 illustrated in FIG. 6. Thereby, the dispensing nozzle 142 may move from a standby part 144 installed outside the positive side of the Y direction of the cup 132 to an upper portion of the center of the wafer W in the cup 132 and move in a radial direction of the wafer W on the surface of the wafer W. The arm 141 may be raised/lowered by the nozzle driver 143 and may adjust the height of the dispensing nozzle 142. The dispensing nozzle 142 is connected to a supplier (not illustrated) that supplies the phosphoric acid liquid to the dispensing nozzle 142.

A discharge nozzle 146 is supported on the arm 145 as illustrated in FIGS. 5 and 6. The discharge nozzle 146 discharges a rinsing liquid. The rinsing liquid is, for example, deionized water (DIW). The arm 145 is movable on the rail 140 by a nozzle driver 147 illustrated in FIG. 6. Thereby, the dispensing nozzle 146 may move from a standby part 148 installed outside the negative side of the Y direction of the cup 132 to an upper portion of the center of the wafer W in the cup 132 and move in a radial direction of the wafer W on the surface of the wafer W. The arm 145 may be raised/lowered by the nozzle driver 147 and may adjust the height of the dispensing nozzle 146. The dispensing nozzle 146 is connected to a supplier (not illustrated) that supplies the rinsing liquid to the dispensing nozzle 146.

The configurations of the development processing unit 30, the SoC film forming unit 31, the SiC film forming unit 32, and the resist coating unit 33 are similar to the configuration of the wet etching unit 34.

### <Irradiation Unit>

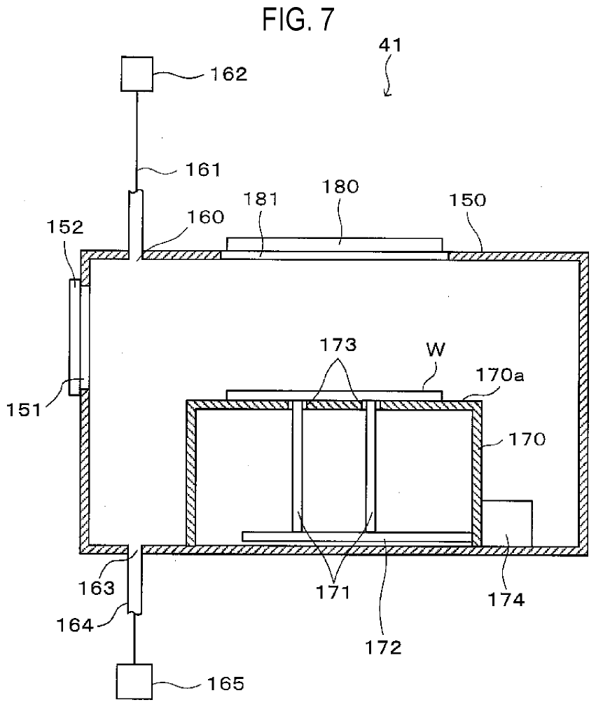

Next, a configuration of the above-mentioned irradiation unit 41 will be described. FIG. 7 is a longitudinal cross-sectional view schematically illustrating the configuration of the irradiation unit 41.

The irradiation unit 41 has a processing container 150, the interior of which is capable of being closed, as illustrated in FIG. 7. A loading/unloading port 151 of the wafer W is formed on a surface facing the wafer transport region D of the processing container 150, and the loading/unloading port 151 is provided with an opening/closing shutter 152.

A gas supply port 160 for supplying gas other than an oxygen gas, for example, an inert gas such as a N₂ gas, toward the inside of the processing container 150 is formed on the upper surface of the processing container 150. A gas supply mechanism 162 is connected to the gas supply port 160 via a gas supply pipe 161. The gas supply mechanism 162 includes, for example, a flow rate control valve (not illustrated) that adjusts a gas flow rate supplied to the processing container 150.

By introducing gas other than the oxygen gas into the processing container 150 by such a gas supply mechanism, the processing container 150 may be under a low-oxygen atmosphere with an oxygen concentration of 0.1 ppm or less.

For example, an exhaust port 163 for exhausting an atmosphere inside the processing container 150 is formed on the lower surface of the processing container 150, and an exhaust mechanism 165 for exhausting the atmosphere inside the processing container 150 through an exhaust pipe 164 is connected to the exhaust port 163. The exhaust mechanism 165 includes an exhaust pump (not illustrated).

By introduction of gas other than oxygen gas from the gas supply port 160 and exhaustion from the exhaust port 163, the atmosphere inside the processing container 150 may be quickly replaced with a low-oxygen atmosphere of 0.1 ppm or less.

A support body 170 of a cylindrical shape on which the wafer W is horizontally placed is provided inside the processing container 150. A lifting pin 171 for delivering the wafer W is supported by a support member 172 and installed inside the support body 170. The lifting pin 171 is provided so as to penetrate a through hole 173 formed in an upper surface 170a of the support body 170 and, for example, three lifting pins 171 are provided. A drive mechanism 174 for raising and lowering the lifting pin 171 by raising and lowering the support member 172 is provided at a base end of the support member 172. The drive mechanism 174 has a drive source (not illustrated) such as a motor that generates a drive force for raising and lowering the support member 172.

A light source 180, such as a deuterium lamp or an excimer lamp, that irradiates the wafer W on the support body 170 with, for example, ultraviolet rays having a wavelength of 172 nm is provided in an upper portion of the processing container 150. The light source 180 may irradiate the entire surface of the wafer W with ultraviolet rays. A window 181 that transmits ultraviolet rays from the light source 180 is provided on the top plate of the processing container 15. The wavelength of the ultraviolet rays is not limited to 172 nm, but is, for example, 150 nm to 250 nm.

### <Wafer Processing>

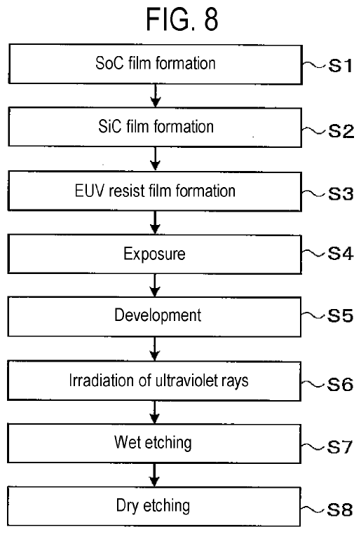

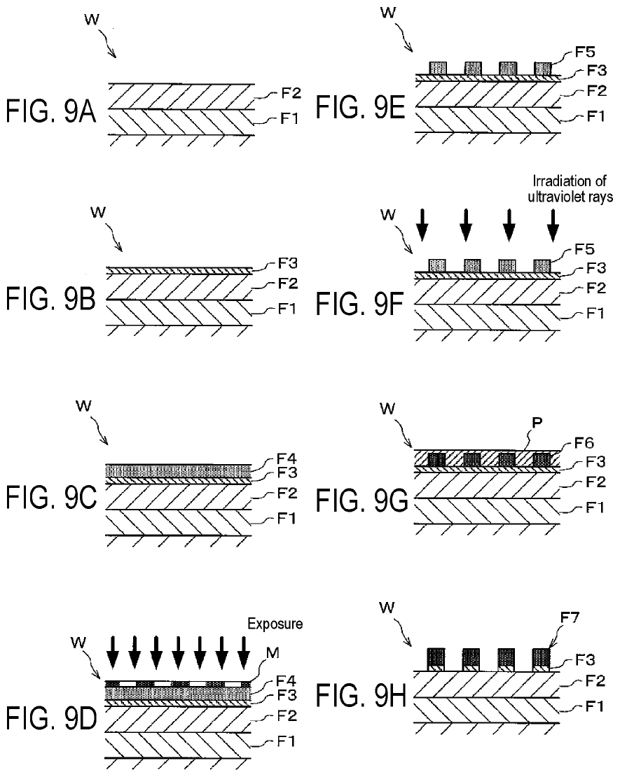

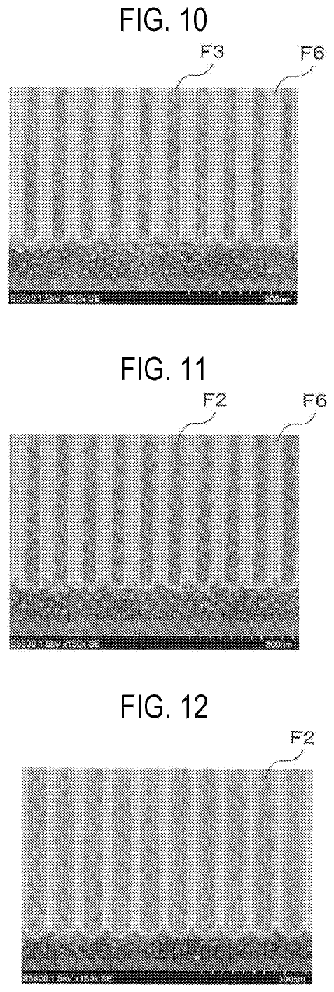

Next, wafer processing performed using the wafer processing system 1 configured as described above will be described. FIG. 8 is a flowchart illustrating main processes of an example of wafer processing. FIGS. 9A to 9H and 10 are schematic partial cross-sectional views illustrating a state of the wafer W in each process of wafer processing. As illustrated in FIG. 9A, a SiO₂ film F1 as an etching target layer has been previously formed on the surface of the wafer W on which wafer processing is performed.

In wafer processing using the wafer processing system 1, first, a cassette C accommodating wafers W is loaded into the cassette station 10 of the coating and developing processing apparatus 2. The wafers W in the cassette C are then transported to the processing station 11 and temperature-controlled in the heat treatment unit 40.

### (Step S1)

Thereafter, as illustrated in FIG. 8 and FIG. 9A, a SOC film F2 is directly formed on the SiO₂ film F1 formed on the wafer W.

Specifically, the wafer W is transported to the SoC film forming unit 31, and a coating liquid for the SoC film is spin-coated onto the surface of the wafer W. The SoC film F2 is formed so as to cover the SiO₂ film F1.

Next, the wafer W is transported to the heat treatment unit 40 and is thermally treated.

The thickness of the SoC film F2 after thermal treatment by the heat treatment unit 40 is, for example, 50 to 100 nm.

### (Step S2)

Subsequently, a SiC film F3 is formed directly on the SoC film F2 formed on the wafer W.

Specifically, the wafer W is transported to the SiC film forming unit 32, and a coating liquid for the SiC film is spin-coated onto the surface of the wafer W. The SiC film F3 is formed so as to cover the SoC film F2 as illustrated in FIG. 9B.

Next, the wafer W is transported to the heat treatment unit 40 and is thermally treated.

The thickness of the SiC film F3 after thermal treatment by the heat treatment unit 40 is, for example, 7 to 15 nm.

### (Step S3)

Thereafter, as illustrated in FIG. 9C, a chemically amplified resist film F4 is directly formed on the SiC film formed on the wafer W.

Specifically, the wafer W is transported to the resist coating unit 33, and a chemically amplified resist is spin-coated onto the surface of the wafer W. The chemically amplified resist film F4 is formed so as to cover the SiC film F3.

Next, the wafer W is transported to the heat treatment unit 40 and is subjected to a prebaking process.

The film thickness of the resist film F4 after the prebaking process is 30 to 100 nm.

### (Step S4)

Next, the resist film F4 formed on the wafer W is exposed.

Specifically, the wafer W is transported to the exposure apparatus 12 via the interface station 13 and is subjected to exposure processing using a mask M as illustrated in FIG. 9D, so that the resist film F4 on the wafer W is exposed in a desired pattern.

### (Step S5)

Next, the resist film after exposure, formed on the wafer W, is developed to form a resist pattern F5 as illustrated in FIG. 9E.

Specifically, after exposure, the wafer W is transported to the heat treatment unit 40 and is subjected to post-exposure baking processing.

Next, the wafer W is transported to the development processing unit 30 and is subjected to development processing to form, for example, a line-and-space resist pattern F5. After pattern formation, the wafer W is transported to the heat treatment unit 40 and is subjected to post-baking processing.

Through Steps S1 to S5, the SoC film F2, the SiC film F3, and the resist pattern F5 are successively formed on the wafer W in this order from below (i.e., no other film exists between the films).

### (Step S6)

Subsequently, as illustrated in FIG. 9F, the wafer W is irradiated with ultraviolet rays to insolubilize the resist pattern F5 with respect to a phosphoric acid solution.

Specifically, the wafer W is transported to the irradiation unit 41. Then, the entire wafer W placed on the support body 170, i.e., the entire resist pattern F5, is irradiated with ultraviolet rays from the light source 180 in a low-oxygen atmosphere with an oxygen concentration of 0.1% or less. In this case, an exposure amount is, for example, 2,000 mJ/cm² or more. The reason for performing irradiation of ultraviolet rays in the low-oxygen atmosphere is that, if oxygen concentration is not low, ozone is generated by irradiation of ultraviolet rays and the resist pattern F5 is removed by this ozone.

### (Step S7)

Subsequently, the phosphoric acid solution is supplied to the wafer W to remove the SiC film F3 exposed from the resist pattern F6 which is insolubilized with respect to the phosphoric acid solution. That is, wet etching is performed using the resist pattern F6 insolubilized with respect to the phosphoric acid solution as a mask.

Specifically, the wafer W is transported to the wet etching unit 34. Then, as illustrated in FIG. 9G, a phosphoric acid solution P from the dispensing nozzle 142 is spin-coated, for example, onto the surface of the wafer W held on the spin chuck 130, and the SiC film F3 is removed using the resist pattern F6 as a mask. The SiC film F3 is removed, for example, until the SoC film F2 is exposed, as illustrated in FIG. 9H. Thereby, a stacked film pattern F7 of the resist film and the SiC film is formed. The phosphoric acid solution supplied to the wafer W has, for example, a mass percent concentration of 85 to 95 wt % and a temperature of 150 degrees C. or higher.

After the phosphoric acid solution is supplied from the dispensing nozzle 142, a rinsing liquid from the discharge nozzle 146 is spin-coated, for example, onto the surface of the wafer W held on the spin chuck 130, and the phosphoric acid solution on the wafer W is removed.

Thereafter, the supply of the rinsing liquid is stopped and, in this state, the wafer W held on the spin chuck 130 is rotated, so as to dry the wafer W thereby.

Removal, i.e., etching, of the SiC film F3 by the phosphoric acid solution is isotropically performed, but the thickness of the SiC film F3 is as thin as 7 to 15 nm as described above. Therefore, if the line width of the resist pattern F5 is about 30 nm to 100 nm, pattern collapse will not occur even if the SiC film F3 is etched by the phosphoric acid solution until the SoC film F2 is exposed.

After the wet etching is completed, the wafers W are sequentially accommodated in the cassette C and are transported to the etching processing apparatus 3.

It is known that the SiC film F3 is capable of being wet-etched with the phosphoric acid solution. However, as a result of examination by the inventors of the present application, a resist pattern for EUV and the like was soluble in the phosphoric acid solution in a normal state. Therefore, the inventors of the present invention conducted extensive studies and found that the resist pattern is insoluble with respect to the phosphoric acid solution by irradiating the resist pattern with ultraviolet rays as in Step S7 described above. The present disclosure is based on this knowledge.

### (Step S8)

Thereafter, dry etching is performed on the wafer W in the etching processing apparatus 3, and the resist pattern F6 is transferred to the SoC film.

Specifically, dry etching of the SoC film F2 (first dry etching) is performed using the stacked film pattern F7 of the resist film and the SiC film as a mask. Next, dry etching of the SiO₂ film F1 (second dry etching) as an etching target is performed using, as a mask, the SoC film F2 to which the resist pattern F6 (a pattern of the resist pattern F6) has been transferred by the first dry etching. The first dry etching and the second dry etching are performed in different processing containers.

In this way, wafer processing using the wafer processing system 1 is completed.

### <Another Example of Wafer Processing>

In the above example, when the SiC film F3 is removed using the resist pattern F6 as a mask by wet etching using the phosphoric acid solution, the SiC film F3 is removed until the SoC film F2 underlying the SiC film F3 is exposed. However, if the SiC film is made thicker than 15 nm for dry etching of the SiC film using the SiC film as a mask, only a part of the upper side of the SiC film may be removed so as not to generate pattern collapse by wet etching during wet etching using the phosphoric acid liquid. Then, the remainder of the SoC film may be removed by dry etching using the resist pattern as a mask in the etching processing apparatus 3. That is, both wet etching using the resist pattern insolubilized with respect to the phosphoric acid solution as a mask and dry etching may be performed. Even in this case, if the thickness of the SiC film and the amount of wet etching of the SiC film using a nitric acid solution are appropriately configured, the resist pattern will not disappear while the resist pattern is being transferred to the SiC film F3.

### <Main Effects>

As described above, in the present embodiment, the resist pattern is insolubilized with respect to the phosphoric acid solution by irradiating the wafer W on which the SoC film, the SiC film, and the resist pattern are sequentially stacked from below with ultraviolet rays. In this embodiment, when the resist pattern is transferred to the SiC film, only wet etching using the resist pattern insolubilized with respect to the phosphoric acid solution as a mask is performed, or both wet etching using the resist pattern insolubilized with respect to the phosphoric acid solution as a mask and dry etching are performed. Therefore, according to this embodiment, when the resist pattern is transferred to the SiC film, unlike a conventional case in which only dry etching is performed, pattern collapse does not occur even if the resist pattern is thin. Further, since the resist pattern does not disappear during transfer, the transfer may be appropriately performed.

FIG. 10 is a diagram illustrating an SEM image of a wafer after being irradiated with ultraviolet rays at an exposure amount of 2,000 mJ/cm² in a state in which the wafer is formed by sequentially stacking a SoC film, a SiC film, and a resist pattern (having a thickness of approximately 50 nm and a line width of approximately 20 nm) from below on a Si bare wafer. FIG. 11 is a diagram illustrating an SEM image of a wafer after being immersed in a phosphoric acid solution with a concentration of 85 wt % and a temperature of 150 degrees C. for 90 seconds in a state in which the wafer is irradiated with ultraviolet rays. FIG. 12 is a diagram illustrating an SEM image of a wafer after being subjected to ashing processing in a state in which the wafer is wet-etched under the above conditions.

After irradiation with ultraviolet rays, a SiC film F3 is exposed from a resist pattern F6, as illustrated in FIG. 10.

Furthermore, as illustrated in FIGS. 10 and 11, changes have occurred in portions not covered by the resist pattern F6 due to wet etching.

As illustrated in FIG. 12, portions of a SoC film F2, not covered by the resist pattern, are removed by ashing processing. Thereby, it can be appreciated that, in FIG. 11 illustrating a state before ashing processing, portions exposed from the resist pattern F6 are not the SiC film F3 but the SoC film F2.

In other words, FIGS. 10 to 12 show that, by performing irradiation of ultraviolet rays and wet etching using the phosphoric acid solution under the above conditions, the resist pattern F6 may be transferred to the SiC film F3 without generating pattern collapse.

### <Modified Example of Wet Etching Unit>

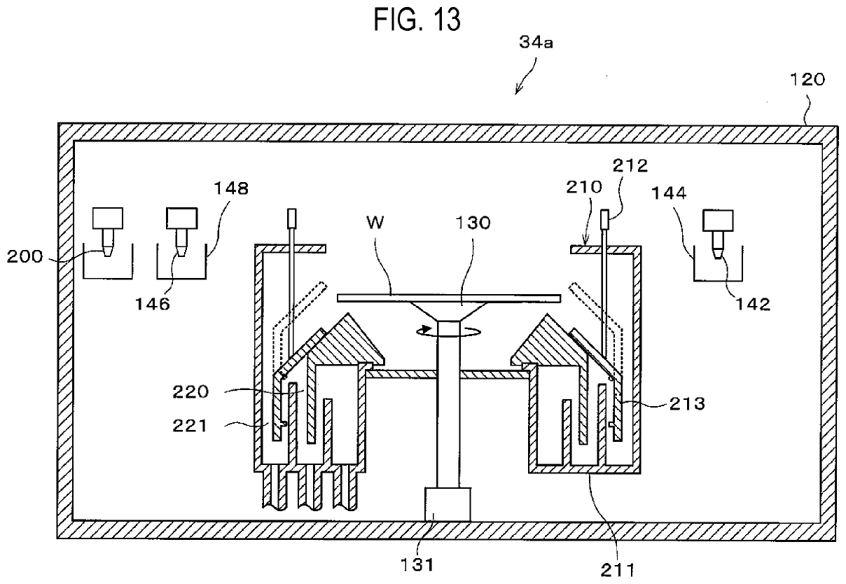

FIG. 13 is a longitudinal cross-sectional view schematically illustrating another example of the wet etching unit.

A wet etching unit 34a of FIG. 13 is configured integrally with a developing unit by the same module and shares constituent members with the developing unit.

Specifically, the wet etching unit 34a includes a dispensing nozzle 142 that dispenses a nitric acid solution, a dispensing nozzle 146 that dispenses a rinsing liquid, and a dispensing nozzle 200 that dispenses a developing liquid.

The dispensing nozzle 142 and the dispensing nozzle 200 share a spin chuck 130, a cup 210, and the like.

As a result, the size of an apparatus may be suppressed from increasing.

The cup 210 includes a cup body 211 and a movable cup 213, which is capable of being raised and lowered relative to the cup body 211 by a lifting mechanism 212. For example, the movable cup 213 is raised during wet etching, and thus a phosphoric acid solution or a rinsing liquid scattered from a rotating wafer W passes through the lower side of the movable cup 213 and is introduced into an inner flow path 220 of the cup body 211. For example, the movable cup 213 is lowered during development processing, and thus a developing liquid or a rinsing liquid scattered from the rotating wafer W passes through the upper side of the movable cup 213 and is introduced into an outer flow path 221 of the cup body 211. As a result, the waste liquid of the phosphoric acid solution and the waste liquid of the developing liquid may be separately collected without being mixed.

### <Other Modifications>

Although the SoC film has been used as the organic film in the above examples, other organic films may be used. Further, although the organic film has been formed by the coating and developing processing apparatus 2, a film forming apparatus that performs film formation by, for example, CVD or ALD, outside the coating and developing processing apparatus 2 may be used.

In the above examples, while the SiC film has been used as the silicon-containing inorganic film, other silicon-containing organic films (e.g., a siloxane-based film used as a SiARC film) may be used. Further, like the organic film, the silicon-containing inorganic film may also be formed by the film forming apparatus that performs film formation, for example, by CVD or ALD, outside the coating and developing processing apparatus 2.

Additionally, wet etching may be performed as follows.

That is, before the phosphoric acid solution is supplied, DIW, which is also used as a rinsing liquid, may be supplied to a wafer W on which a resist pattern is formed, so that a DIW puddle that covers the resist pattern may be formed. Next, the phosphoric acid solution at normal temperature (room temperature) may be supplied to the wafer W to form a phosphoric acid solution puddle by replacing the DIW on the wafer W by the phosphoric acid solution.

Thereafter, the phosphoric acid solution puddle may be heated to a predetermined temperature by a heater provided in the spin chuck 130, and the SiC film may be removed by the phosphoric acid solution using the resist pattern as a mask.

Then, a rinsing liquid may be supplied to the wafer W to remove the phosphoric acid solution on the wafer W and then the wafer W may be dried.

It is to be noted that the embodiments disclosed herein are exemplary in all respects and are not restrictive. The above-described embodiments may be omitted, replaced, modified, and/or combined in various forms without departing from the scope and spirit of the appended claims. The structural requirements of the above-described embodiment can be arbitrarily combined as long as the above effects are not impaired. Further, the technology according to the present disclosure may have other effects that are obvious to those skilled in the art from the description of this specification, in addition to or in place of the above effects.

### EXPLANATION OF REFERENCE NUMERALS

2: Coating and developing processing apparatus, 34, 34a: Wet etching unit, 41: Irradiation unit, F2: SoC film, F3: SiC film, F5: Resist pattern, F6: Resist pattern insolubilized with respect to phosphoric acid solution, P: Phosphoric acid solution, W: Wafer

What is claimed is:

1. A substrate processing method, comprising:
insolubilizing a resist pattern with respect to a phosphoric acid solution by irradiating a substrate, on which an organic film, a silicon-containing inorganic film, and the resist pattern are sequentially stacked in this order from below, with ultraviolet rays;
after the insolubilizing the resist pattern, removing the silicon-containing inorganic film exposed from the resist pattern by supplying the phosphoric acid solution to the substrate; and
after the removing the silicon-containing inorganic film, transferring the resist pattern to the organic film by performing an etching process on the substrate.

2. The substrate processing method of claim 1, wherein the resist pattern is formed of a chemically amplified resist.

3. The substrate processing method of claim 2, wherein the chemically amplified resist is an ArF resist, a KrF resist, or an EUV resist.

4. The substrate processing method of claim 1, wherein an amount of irradiation of the ultraviolet rays is 2,000 mJ/cm² or more.

5. The substrate processing method of claim 2, wherein an amount of irradiation of the ultraviolet rays is 2,000 mJ/cm² or more.

6. The substrate processing method of claim 3, wherein an amount of irradiation of the ultraviolet rays is 2,000 mJ/cm² more.

7. The substrate processing method of claim 1, wherein a temperature of the phosphoric acid solution is 150 degrees C. or higher.

8. The substrate processing method of claim 2, wherein a temperature of the phosphoric acid solution is 150 degrees C. or higher.

9. The substrate processing method of claim 3, wherein a temperature of the phosphoric acid solution is 150 degrees C. or higher.

10. The substrate processing method of claim 4, wherein a temperature of the phosphoric acid solution is 150 degrees C. or higher.

11. A substrate processing apparatus, comprising:
a reformer configured to irradiate a substrate, on which an organic film, a silicon-containing inorganic film, and a resist pattern are sequentially stacked from below, with ultraviolet rays so as to insolubilize the resist pattern with respect to a phosphoric acid solution; and
a wet etcher configured to supply the phosphoric acid solution to the substrate on which the resist pattern is insolubilized so as to remove the silicon-containing inorganic film exposed from the resist pattern.

12. The substrate processing apparatus of claim 11, wherein the resist pattern is formed of a chemically amplified resist.

13. The substrate processing apparatus of claim 12, wherein the chemically amplified resist is an ArF resist, a KrF resist, or an EUV resist.

14. The substrate processing apparatus of claim 11, wherein an amount of irradiation of the ultraviolet rays is 2,000 mJ/cm² or more.

15. The substrate processing apparatus of claim 11, wherein a temperature of the phosphoric acid solution is 150 degrees C. or higher.

16. The substrate processing apparatus of claim 11, further comprising a developer configured to form the resist pattern by performing developing processing,
wherein the wet etcher and the developer are configured by a same module to share a part of constituent members.

17. A substrate processing system, comprising:
a substrate processing apparatus including a reformer configured to irradiate a substrate, on which an organic film, a silicon-containing inorganic film, and a resist pattern are sequentially stacked from below, with ultraviolet rays so as to insolubilize the resist pattern with respect to a phosphoric acid solution, and a wet etcher configured to supply the phosphoric acid solution to the substrate on which the resist pattern is insolubilized so as to remove the silicon-containing inorganic film exposed from the resist pattern; and
an etching apparatus configured to transfer the resist pattern to the organic film by performing an etching process on the substrate from which a part exposed from the resist pattern in the silicon-containing inorganic film is removed.

18. The substrate processing system of claim 17, wherein the resist pattern is formed of a chemically amplified resist.

19. The substrate processing system of claim 17, wherein an amount of irradiation of the ultraviolet rays is 2,000 mJ/cm² or more.

20. The substrate processing system of claim 17, wherein a temperature of the phosphoric acid solution is 150 degrees C. or higher.
